(19) United States
(12) Patent Application Publication
(10) Pub. No.: US 2017/0088460 A1
(43) Pub. Date: Mar. 30, 2017

(54) GLAZING FOR SOLAR PROTECTION PROVIDED WITH THIN-FILM COATINGS

(71) Applicant: SAINT-GOBAIN GLASS FRANCE, Courbevoie (FR)

(72) Inventor: Alexandre MAILLET, Compiegne (FR)

(73) Assignee: SAINT-GOBAIN GLASS FRANCE, Courbevoie (FR)

(21) Appl. No.: 15/315,876

(22) PCT Filed: Jun. 2, 2015
(86) PCT No.: PCT/FR2015/051452

§ 371 Date: Dec. 2, 2016

(30) Foreign Application Priority Data
Jun. 4, 2014 (FR) 1455067

(51) Int. Cl. C03C 17/34; C03C 17/32; E06B 3/67; C23C 14/08; C23C 14/06; E06B 9/24; C03C 17/245; C23C 14/34

(52) U.S. Cl. CPC C03C 17/3417; C03C 17/2456; C03C 17/3435; C03C 17/32; C23C 14/34; C23C 14/083; C23C 14/08; C23C 14/0652; E06B 9/24; E06B 3/6715; C03C 2217/212; C03C 2218/152; C03C 2218/365; C03C 2218/154; C03C 2218/32; E06B 2009/2417

(57) ABSTRACT

A solar protection glazing includes a substrate covered with a coating of dielectric materials on each of its faces. The substrate is preferably a glass substrate. Each of the coatings consists of a layer based on titanium oxide or of a stack of layers of dielectric materials incorporating such a layer. The thickness of the layers based on titanium oxide in each of the coatings is between 10 and 70 nm.

The invention relates to insulating glazings comprising stacks of thin layers which act on solar radiation and are intended more particularly for solar protection.

The glazing according to the invention is more particularly suitable for fitting buildings, even though it is not limited thereto. It is in particular also possible to use it in the automobile field, as a side window, sunroof or else rear window or else as an oven door.

In a known manner, by selecting the chemical nature, the thicknesses and the succession of the thin layers constituting the stack, it is possible to act significantly on the amount of energy resulting from solar radiation entering a premises or a passenger compartment. In particular, such a glazing makes it possible to prevent excessive heating inside said premises or passenger compartment in summer and thus contributes to limiting the consumption of energy required for the air-conditioning thereof. For the purposes of the present invention, the term “solar protection glazing” or “anti-sun glazing” or else “insulating glazing” is therefore intended to mean a glazing consisting of a substrate, usually made of glass, coated with a thin layer or thin layers, such that the amount of solar radiation in particular visible and near infrared radiation) which passes through said glazing is substantially reduced, with reference to that which passes through the same substrate but taken in isolation.

The invention also relates to such a glazing used as a spandrel panel once opacified, so as to be part of a facade facing panel, and which makes it possible to provide, in combination with vision glazings, buildings with exterior surfaces which are entirely glazed and uniform.

These layered glazings (and spandrel panels) are subject to a certain number of constraints: with regard to glazings, the layers used must firstly sufficiently screen out solar radiation, i.e. they must allow thermal insulation while allowing, however, a substantial part of the light to pass through, as measured by the light transmission T_{L}. In addition, these thermal performances must preserve the optical and esthetic appearance of the glazing: it is thus desirable to be able to modulate the level of light transmission of the substrate, while at the same time keeping a color judged to be esthetic and preferably substantially neutral, most particularly in external reflection, or even in transmission. This is also true for spandrel panels with regard to the appearance in reflection.

According to another essential aspect, these layers must also be sufficiently durable, all the more so if, in the glazing once installed, they are on one of the exterior faces of the glazing (as opposed to the “interior” faces, turned towards the intermediate gas-filled cavity of a double glazing for example).

There is another constraint which strongly arises today: when the glazings at least partially consist of glass substrates, the latter very often undergo one or more heat treatments, for example of the betiding type if it is desired to give them a curved shape (shop window), or else of the tempering or annealing type if it is desired for them to be more resistant and therefore less hazardous in the event of impacts.

While depositing the layers after the heat treatment of the glass is complex and expensive, it is also known that depositing the layers on the glass before carrying out said heat treatment can cause a substantial modification of the properties, in particular optical and energy properties, of said stacks.

It is thus sought to obtain, and this is the subject of the present invention, thin-layer stacks which can be capable of withstanding heat treatments without significantly modifying the optical/thermal properties of the glazing as a whole and without modification/degradation of its general appearance observed before tempering. In particular, in such a case, reference will be made to “bendable” or “temperable” layers.

An example of anti-sun glazing for buildings is given in patents EP-0 511 901 and EP-0 678 483: these concern functional layers for screening out solar radiation which are made of nickel-chromium alloy, optionally nitrided, of stainless steel or of tantalum, and which are placed between two dielectric layers of metal oxide such as SnO₂, TiO₂ or Ta₂O₅. These glazings are good anti-sun glazings and have satisfactory mechanical and chemical durabilities, but are not truly “bendable” or “temperable”, since the layers of oxide surrounding the functional layer cannot prevent its oxidation during the bending or tempering operation, said oxidation being accompanied by a modification of the light transmission and of the appearance in general of the glazing as a whole.

Many studies have recently been carried out in order to make the layers bendable/temperable in the field of low-emissivity glazings, which instead target high light transmissions contrary to anti-sun glazings. It has already been proposed to use, on top of functional layers of silver, layers of dielectric based on silicon nitride, this material being relatively inert with respect to high-temperature oxidation and proving to be capable of preserving the underlying silver layer, as is described in patent EP-0 718 250.

Other stacks of layers which act on solar radiation and which are presumed to be bendable/temperable have been described, having recourse to functional layers other than silver: patent EP-0 536 607 uses functional layers of a metal nitride, of the TiN or CrN type, with protective layers of metal or of silicon derivatives, patent EP-0 747 329 describes functional layers of nickel alloy of the NiCr type, combined with layers of silicon nitride.

Stack structures using titanium dioxide (TiO₂) or zirconium dioxide (ZrO₂) as the layer which acts mainly on solar radiation, this layer being deposited on an underlayer of silicon nitride, are known, moreover, from patent application WO 2007/028913.

Such a product has thus appeared to be relatively effective with regard to its properties of reflecting the heat from solar radiation and relatively simple and economical to deposit using the magnetically enhanced sputtering (magnetron sputtering) technique.

As described in application WO 2007/028913, the depositing of a stack of the type previously described using vacuum techniques for spraying targets makes it possible to deposit stacks of layers of which the thickness can be controlled to within a nanometer, thereby enabling the desired colorimetry of the glazing to be adjusted, in particular its colorimetric neutrality. It is indicated in this publication that the stack thus deposited is also satisfactory from the point of view of its to mechanical temperature resistance properties, in particular under heat treatment conditions around 600-630° C., characteristic of the most common tempering or bending processes. In particular, the glazing according to application WO 2007/028913, having undergone such a heat treatment, does not exhibit any notable modifications of its properties, whether in terms of energy performance levels or colorimetry.

When provided with such a stack and depending essentially on the thickness of the layer based on titanium oxide, the &zings with anti-sun properties obtained have a light transmission rid coefficient of about 75% to 60% and a light reflection (RL) coefficient of about 25% to 40%. The solar factor through the glazing is, however, at least about 65%, within the meaning of standard NF EN410(2011), which may be considered to he insufficient under exterior conditions of very strong sunshine.

An object of the present invention is thus to provide &zings of the same type as those described in application WO 2007/028913, i.e. the functional layers of which are based on titanium oxide, but the insulation performance of which is improved, in particular the solar factor of which is less than 60%, or even less than 55%, while at the same time retaining a sufficient light transmission, in particular greater than or equal to 40%, or even greater than or equal to 45% within the meaning of standard NF EN410(2011).

According to another important characteristic of the glazings according to the present invention, they usually have a very low colorimetry within the meaning previously described, including after heat treatment such as bending or tempering or even enameling. Likewise, it is possible for such glazings to be used in the construction field as spandrel glazing once at least partially or most commonly totally opacified.

Spandrel glazing, more often called spandrel in the field, can, for example, make it possible to hide construction elements such as electrical cabling, plumbing, air-conditioning or, more generally, all the structural elements of the building.

In particular, in buildings which incorporate very large glazed areas, the use of spandrel glazings is advantageous for observing the esthetics and the architectural unity of the large glazed area, which can cover virtually the entire surface area of the building.

More specifically, for such buildings, given the significant size of Is the glazed surface areas, the glazings used must comprise, over their entire surface area, stacks which have solar control properties that make it possible to limit the cost of air-conditioning in summer and preferably interior thermal insulation properties that make it possible to reduce the losses of energy from the building in winter. The glazings, present over virtually the entire surface area of the building, therefore cover both the parts which must offer significant light transmission (then called vision glazing) and those of which the transmission must be virtually zero (eclipsing effect) in order to hide the structural elements of the building (spandrel glazing). For this purpose, it is normal to use layers of opaque enamel to obtain such masking.

The objective of the invention is then to develop a glazing comprising a substrate of glass type bearing coatings of thin layers which act on incident solar radiation, which makes it possible to solve the problems as previously set out. In particular, the glazing desired according to the invention has thermal properties suitable for the solar protection of buildings, and also optical properties, in particular colorimetry and light transmission properties, which are also suitable for such a use, and also an ability to withstand heat treatments without damage, consisting of tempering, bending or else enameling, even at very high temperature, i.e. greater than or equal to 650° C.

In its most general form, the present invention relates to a solar protection glazing comprising a substrate, preferably a glass substrate, said substrate being covered with a coating consisting of dielectric materials on each of its two faces. In the glazing according to the invention, each of said coatings consists of a layer based on titanium oxide or of a stack of layers of dielectric materials incorporating such a layer based on titanium oxide. According to the present invention, the physical thickness of the layers based on titanium oxide, in each of said coatings, is between 10 and 70 nm.

In addition to the layer based on titanium oxide, a thin-layer stack according to the present invention therefore comprises only layers consisting of dielectric materials and therefore does not comprise in particular layers of metallic nature, in particular of the type of those. previously described for their infrared radiation reflection and/or absorption properties, in particular those consisting of precious metals such as Ag, Pt, Pd, Au or else Cu, nor layers made of metal nitride, of the TiN or CrN type, or else based on nickel, such as NiCr, or on Nb or niobium nitride.

For the purposes of the present invention, the layers based on titanium oxide very predominantly comprise the elements O and Ti, in a ratio preferentially close to 2 (even though differences from this theoretical value are of course possible without departing from the context of the present invention, in particular according to the conditions for depositing said layer or else a possible doping of said layer). In particular, Ti and O together represent according to the invention at least 85% of the atoms present in the layer, and preferentially at least 90%, or even at least 95%, of the atoms present in the laver.

According to possible and preferred embodiments of the present invention, which may of course be combined with one another as appropriate:
Said dielectric materials are chosen from the nitrides, oxides or oxynitrides.
The dielectric materials, besides the layers based on titanium oxide, are chosen from zinc oxides, silicon oxides, tin oxides, zinc tin oxides, silicon and/or aluminum nitrides, and silicon and/or aluminum oxynitrides.
At least one of said coatings, possibly both coatings, consists of a stack according to the succession of the following layers, starting from the surface of the glass:
   an underlayer or a set of underlayers, said underlayer(s) consisting of dielectric materials,
   a layer based on titanium oxide, the physical thickness of which is between 10 and 70 nm.

Preferably, such a stack also comprises an overlayer or a set of overlayers, said overlayer(s) consisting of dielectric materials. Such a stack preferentially has the following characteristics:
The overall optical thickness of the underlayer(s) is between 30 and 90 nm, more preferably 40 and 70 nm.
The overall optical thickness of the overlayer(s) is between 7 and 30 nm, more preferably between 10 and 20 mn.
The glazing comprises, between the surface of the glass and the layer based on titanium oxide, two underlayers, including one layer based on silicon oxide, the physical thickness of which is preferably between 10 and 20 nm, and one layer based on silicon nitride, the physical thickness of which is preferably between 15 and 25 nm.
The glazing comprises, between the surface of the glass and the layer based on titanium oxide, a single underlayer based on silicon nitride, the physical thickness of which is preferably between 15 and 35 nm.
The glazing comprises, on top of the layer based on titanium oxide, the succession of an overlayer based on silicon oxide, preferably having a physical thickness of between 5 and 10 nm, and of an overlayer based on titanium oxide, preferably having a thickness of between 1 and 3 nm.
At least one of said coatings, or even both coatings, consists of a single layer based on titanium oxide, preferably deposited by pyrolysis.
The glazing comprises, on a first face of the substrate, a first coating deposited by CVD, in particular by pyrolysis, and, on a second face of the substrate, a second coating deposited by a vacuum deposition technique, in particular a sputtering technique. In particular, according to this embodiment, the coating deposited by pyrolysis is a layer based on titanium oxide and the coating deposited by a vacuum deposition technique is a stack of layers which consists of the succession of the following layers, starting from the surface of the glass:
   an underlayer or a set of underlayers, said underlayer(s) consisting of dielectric materials,
   a layer used on titanium oxide, the thickness of which is between 10 and 70 nm.
Preferably, such a stack also comprises an overlayer or a set of overlayers, said overlayer(s) consisting of dielectric materials.
Of course, the preferred embodiments of such a stack as previously described apply to this implementation.
According to another implementation, the glazing comprises, on each of its faces, a coating deposited by a vacuum technique and consisting of the succession of the following lavers, starting from the surface of the glass:
   an underlayer or a set of underlayers, said underlayer(s) consisting of dielectric materials,
   a layer based on titanium oxide, the physical thickness of which is between 10 and 70 nm.

Preferably, such a stack also comprises an overlayer or a set of overlayers, said overlayer(s) consisting of dielectric materials. According to another alternative, at least one of the coatings deposited by a vacuum technique, or even both coatings, may consist of a single layer based on titanium oxide.

Of course, the preferred embodiments of such a stack as previously described apply to this implementation.
At least one layer based on titanium oxide also comprises an element X chosen from silicon, zirconium, niobium and tantalum, the overall X/Ti atomic ratio in said layer being between 0.01 and 0.25, Ti and X representing at least Si and Ti represent at least 90% of the atoms other than oxygen, preferably at least 95%, or even at least 97%, or even all of the atoms other than oxygen. According to such an embodiment, X is very preferentially silicon.

According to such an embodiment in which X is silicon.
According to a first implementation, said Si/Ti ratio is homogeneous throughout the thickness of the layer based on titanium oxide.
According to another embodiment, different than the previous one, the layer based on titanium oxide comprises a succession of strata in which the Si/Ti ratio ranges between 0 and 0.20.
The overall Si/Ti atomic ratio in the layer is between 0.05 and 0.20, more preferably is between 0.05 and 0.15.
According to one alternative or supplementary embodiment, at least one layer based on titanium oxide, or even all of the layers based on titanium oxide, in said coatings, essentially consist(s) of titanium and oxygen.
Said layer(s) based on titanium oxide comprise(s) in particular less than 1 mol % of elements other than titanium and oxygen.
The thickness of the layers based on titanium oxide in each coating is between 20 and 60 nanometers, preferably between 30 and 55 nm.
The light reflection on each of the faces of the glazing is greater than 30%.
The solar factor of the glazing is less than 60%, preferably the sc factor is less than 55%.
The light, transmission of the glazing is between 45% and 60%.
The glazing has undergone a heat treatment of the bending, tempering and/or annealing type.

According to the invention, the overlayer(s) or underlayer(s) made of dielectric materials of the stack, in particular those which are based on silicon, in particular on silicon oxide, nitride or oxynitride, may also contain a metal which is minor compared with the silicon, for example aluminum, for example up to 10 mol % relative to the silicon. This is in particular useful for accelerating the depositing of the layer by reactive magnetron sputtering, where the silicon target is made more conductive by “doping” with aluminum. For the purposes of the present invention, it is thus more generally intended for the overlayers or underlayers made of dielectric materials to essentially consist of said materials, without, however, excluding that other elements, in particular other cations, are present, but in very minor amounts, in particular for the purpose of facilitating the depositing of the layers by means of the processes used, most particularly magnetron sputtering.

Unless otherwise indicated, all the thicknesses described in the present. application are actual thicknesses. For the purposes of the present invention, the term “optical thicknesses” is intended to mean conventionally the product of its actual (physical) thickness multiplied by its refractive index. Thus, an optical thickness of 50 nm of Si₃N₄, the refractive index of which is approximately 2.0, corresponds to a deposit of 25 nanometers (physical thickness) of said material.

A subject of the invention is “monolithic” glazings (i.e. consisting of a single substrate) or insulating multiple glazings of the double glazing or even triple glazing type, at least one of the constituents (sheets) of which is a glazing according to the invention.

The glazings on which the invention is more particularly focused have a T_{L} of about from 40% to 60%, in particular between 45% and 60%, and an energy transmission, measured by the solar factor, of around the value of T_{L}, to within 5%. They also preferentially have a relatively neutral coloration with possibly a blue or green color in external reflection (on the side of the substrate not provided with layers), with in particular in the (L*, a*, hi international colorimetry system negative a* and b* values (before and after any possible heat treatment). Thus, an attractive and not very strong color in reflection, desired in the construction industry, is obtained.

For the purposes of the present description, the optical and energy parameters according to the invention are measured according to the data reported in standard NF EN410 (2011 version),

A subject of the invention is also the layered substrate at least partially opacified with a coating of lacquer or enamel type, for the purpose of producing spandrel panels, where the opacifying coating may be in direct contact with the substrate face already coated with the stack of layers. The stack of layers may therefore be completely identical for the vision glazing and for the spandrel panel. The face of the substrate already provided with a stack of thin layers and on which it is possible to deposit, according to conventional techniques, an enamel composition without the appearance of optical defects in the stack, and with very limited optical change, and in particular without the appearance of haze, is considered in particular according to the invention to be “enamelable”. This also means that the stack has satisfactory durability, without any undesirable deterioration of the layers of the stack in contact with the enamel, either while it is being baked or over time once the glazing has been fitted.

Although the application more particularly intended by the invention is glazing for buildings (including residential buildings), it is clear that other applications can be envisioned, in particular in vehicle glazings (apart from windshields, where very high light transmission is required), such as the side windows, sunroof or rear window, or else oven doors.

The advantages of the present invention are illustrated by means of the nonlimiting examples which follow, which are according to the invention and comparative.

All of the substrates are made of 6 mm-thick clear glass of Planilux type sold by the company Saint-Gobain Glass France.

All the layers are deposited by pyrolysis or by well known magnetron sputtering techniques.

More specifically:
the layers based on titanium oxide are deposited either by pyrolysis (spraying of organometallic titanium precursors at the surface of the hot glass exiting the float bath) or using titanium-based metallic targets (the targets being sprayed in an oxidizing atmosphere),
the silicon nitride layers are deposited using a metallic silicon target comprising 8% by weight of aluminum, sprayed in a reactive atmosphere containing nitrogen (40% Ar and 60% N₂). The silicon nitride layers therefore also contain a minor amount of aluminum,
the silicon oxide layers are deposited using a metallic silicon target having the same composition as the previous one, but this time sprayed in an oxidizing reactive atmosphere, according to techniques well known in the field.

### EXAMPLE 1

### Prior Art

In this example obtained in accordance with the teaching of application WO 2007/028913, a stack consisting of an underlayer of silicon nitride, of a layer of titanium oxide TiOₓ and of an overlayer of SiO₂ is deposited on one face of the glass substrate by the magnetron sputtering techniques as previously described.

The glazing provided with its stack is represented schematically by the following sequence:

Glass/SiNₓ (23 nm)/TiOₓ(30 nm)/SiO₂ (7 nm)

### EXAMPLE 2

### Comparative

In this comparative example, a stack of the same nature as that described according to example 1 is deposited on the same substrate with the only difference being that the device is regulated so that the layer of TiOₓ is twice as thick (60 nm),

The glazing provided with its stack is represented schematically by the following sequence:

Glass/SiNₓ (23 nm)/TiOₓ (60 nm)/SiO₂ (7 nm)

### EXAMPLE 3

### Comparative

In this comparative example, a stack of the same nature as that described according to example 1 is deposited on the same substrate with the only difference being that the layer of TiOₓ deposited is even thicker, so as to reach a thickness equal to 70 nm.

The glazing provided with its stack is represented schematically by the following sequence:

Glass/SiNₓ (23 nm)/TiOₓ (70 nm)/SiO₂ (7 nm)

### EXAMPLE 4

### According to the Invention

In this example according to the invention, a stack similar to that described according to example 1 is deposited on a glass substrate of the same type by the vacuum sputtering techniques, The other face is this time provided with a pyrolytic coating of titanium oxide, deposited beforehand on the ribbon of hot glass exiting the float bath, according to the techniques which are standard in the field.

The glazing provided with the two coatings on each of its faces is represented schematically by the following sequence:

TiO_{2 pyro} (30 nm)/Glass/SiNₓ (23 nm)/TiOₓ (30 nm)/SiO₂ (7 nm)

With reference to example 1, according to examples 2 and 3, an overthickness of TiO₂ is deposited within the stack of layers for the purpose of improving the anti-sun performances of the glazing, Alternatively, according to example 4 according to the invention, this same additional amount of TiO₂ is added to the glazing of example 1, but on the other face of the glazing and not within the stack.

The optical properties and the colorimetry of the various glazings thus obtained according to examples 1 to 4 are measured according to the following criteria in accordance with standard NF EN410 (2011):
transmission T_{L}: light transmission as % according to illuminant D₆₅,
light reflection glass side: (RLᵥ) as %,
a*(Rᵥ), b*(Rᵥ): colorimetric coordinates in external reflection according to the L, a*, b* colorimetry system,
light reflection layer side: (RL_{c}) as
a*(R_{c}), b*(R_{c}): colorimetric coordinates in external reflection according to the L*, a*, b* colorimetry system,
solar factor SF as % which measures the ratio of the total energy entering the premises to the incident solar energy.

TABLE 1

| | | | | | | | REFLECTION | | | |
|---|---|---|---|---|---|---|---|---|---|---|
| | | | | REFLECTION LAYER | | | GLASS SIDE | | | SOLAR |
| | TRANSMISSION | | | SIDE (interior) | | | (exterior) | | | FACTOR |
| EXAMPLE | T_{L} | a* | b* | RL_{c} | a*_{(Rc)} | b*_{(Rc)} | RL_{V} | a*_{(Rv)} | b*_{(Rv)} | SF (%) |
| Example 1 | 66 | 0 | 3 | 31 | −2 | −3 | 30 | −3 | −3 | 65 |
| (prior art) | | | | | | | | | | |
| Example 2 | 70 | −1 | −8 | 27 | −1 | 21 | 26 | −1 | 21 | 67 |
| (comparative) | | | | | | | | | | |
| Example 3 | 76 | −4 | −5 | 21 | 7 | 18 | 20 | 6 | 18 | 68 |
| (comparative) | | | | | | | | | | |
| Example 4 | 53 | 0 | 3 | 44 | −2 | −6 | 44 | −3 | −6 | 58 |
| (the invention) | | | | | | | | | | |

The results reported in table 1 indicate the light and energy performances of the glazings according to the three examples.

Comparison of examples 1 to 3 shows that the increase in thickness of the layer of titanium oxide within a stack present on a single face of the glass substrate does not bring about any improvement in the thermal insulation properties of the glazing, as indicated by the solar factor values reported in table 1.

Conversely, the depositing of a layer of titanium oxide corresponding to the thickness of the layer according to example 2, but this time on the other face of the glass substrate (example 4 according to the invention) this time brings about a significant improvement in the energy insulation properties of the glazing, while at the same time preserving a light transmission greater than 50%.

The above stacks are then subjected to the same heat treatment as that indicated in previous application WO 2007/028913, consisting of heating at 620° C. for 10 minutes, followed by air-tempering.

The colorimetry variation ΔE* is defined in the following ay. ΔE*=(ΔL*²+Δa*²+Δb*²)^{1/2}, with ΔL*, Δa* and Δb* the difference in the measurements of L*, a* and b* before and after the heat treatment.

The ΔE* before and after heat treatment is about or close to 1% and all the glazings retain their anti-sun property unchanged, as measured by the SF factor. They are also perfectly calibrated from an esthetic point of view, most particularly in external reflection, where the values of a* and b* are close to zero or slightly negative, giving a very neutral or slightly blue-green color which is accepted for glazings with high external reflection. All the values measured change very weakly under the influence of the heat treatment: the T, and SF values are preserved to within approximately 1%, the colorimetric data change very little, and there is no swing from one tint to another tint in external reflection. No optical defect of microcrack or pinhole type is observed on the three glazings.

### EXAMPLES 5 to 10

### According to the Invention

In these examples, single layers of titanium oxide are deposited, as coating, on each of the faces of the glass substrate Planiluxt, by vacuum sputtering techniques. For each example, various thicknesses are deposited, as reported in table 2 which follows.

The glazing provided with the two layers of titanium oxide is represented schematically by the following sequence:

TiOₓ (x₁ nm)/Glass/TiOₓ (x₂ nm)

The light and energy characteristics of the various glazings obtained are measured as previously indicated and reported in the following table 2:

TABLE 2

| | THICKNESS | THICKNESS | | | | ENERGY |
|---|---|---|---|---|---|---|
| | TiO₂ layer | TiO₂ layer | | | | TRANSMISSION |
| | first face | second face | TRANSMISSION | | | (Solar Factor) |
| EXAMPLE | (x₁) | (x₂) | T_{L} | a* | b* | SF (%) |
| Example 5 | 55 | 10 | 58 | 1 | 1 | 62 |
| (the invention) | | | | | | |
| Example 6 | 55 | 20 | 54 | 1 | 3 | 59 |
| (the invention) | | | | | | |
| Example 7 | 55 | 30 | 50 | 1 | 5 | 56 |
| (the invention) | | | | | | |
| Example 8 | 55 | 40 | 47 | 1 | 4 | 54 |
| (the invention) | | | | | | |
| Example 9 | 55 | 55 | 45 | 2 | 0 | 52 |
| (the invention) | | | | | | |
| Example 10 | 55 | 70 | 47 | 2 | −6 | 53 |
| (the invention) | | | | | | |

The results reported in table 2 show that the solar factor can be brought to much lower values by application of the present invention and can be in particular lowered by 13% (in absolute value) compared with the best performance observed according to the prior art configurations (previous example 1), which appears to be entirely significant for the desired application. Thus, in any event, the energy performances noted for the glazings according to the invention are greater than that which can be obtained according to the teaching of application WO 2007/028913, the light transmission remaining at an acceptable level for use in particular in the construction industry or else as side windows.

1. A solar protection glazing comprising:
a substrate, said substrate being covered with a coating of dielectric materials on each of us faces wherein each of the coatings consists of a layer based on titanium oxide or of a slack of layers of dielectric materials incorporating such a layer, the thickness of the layers based on titanium oxide being between 10 and 70 nm.

2. The solar protection glazing as claimed in claim 1, wherein said dielectric materials are chosen from the nitrides, oxides or oxynitrides,

3. The solar protection glazing as claimed in claim 1, wherein the dielectric materials, besides the layers based on titanium oxide, are chosen from zinc oxides, silicon oxides, tin oxides, zinc tin oxides, silicon and/or aluminum nitrides, and silicon and/or aluminum oxynitrides.

4. The solar protection glazing as claimed in claim 1, wherein at least one of said stacks consists of the succession of the following layers, starting from the surface of the substrate:
an underlayer or a set of underlayers, said underlayer(s) consisting of dielectric materials, and
a layer based on titanium oxide, the thickness of which is between 10 and 70 nm.

5. The solar protection glazing as claimed in claim 4, wherein at least one of said coatings consists of a single layer based on titanium oxide.

6. The solar protection glazing, as claimed in claim 1, further comprising, on a first face of the substrate, a first coating deposited by pyrolysis or by CVD and, on a second face of the substrate, a second coating, deposited by a vacuum deposition technique.

7. The solar protection glazing as claimed in claim 6, wherein the coating deposited by pyrolysis is a layer based on titanium oxide and wherein the coating deposited by a vacuum deposition technique is a stack of layers which consists of the succession of the following layers, starting from the surface of the substrate:
an underlayer or a set of underlayers, said underlayer(s) consisting of dielectric materials, and
a layer based on titanium oxide, the thickness of which is between 10 and 70 nm.

8. The solar protection glazing as claimed in claim 1, wherein at least one of the layers based on titanium oxide also comprises an element X chosen from silicon, zirconium, niobium and tantalum, the overall X/Ti atomic ratio in said layer being between 0.01 and 0.25, Ti and X representing at least 90% of the atoms other than oxygen.

9. The solar protection glazing as claimed in claim 8, wherein X is silicon.

10. The solar protection glazing as claimed in claim 1, wherein at least one of the layers based on titanium oxide essentially consists of titanium and oxygen.

11. The solar protection glazing as claimed in claim 10, wherein said layer(s) based on titanium oxide comprises) less than 1 mol % of elements other than titanium and oxygen.

12. The solar protection glazing as claimed in claim 1, wherein the thickness of the layers based on titanium oxide in each stack is between 20 and 60 nanometers.

13. The solar protection glazing as claimed in claim 1, wherein a light reflection on each of the faces of the glazing is greater than 30%.

14. The solar protection glazing as claimed in claim 1, wherein a solar factor is less than 60%.

15. The solar protection glazing as claimed in claim 1, wherein a light transmission is between 45% and 60%.

16. The glazing as claimed in claim 1, wherein the blazing has undergone a heat treatment of a bending, tempering and or annealing type.

17. A spandrel glazing, comprising:
the solar protection glazing as claimed claim 1, which is at least partially opacified with an additional coating, said coating being in the form of an enamel or of a lacquer.

18. The spandrel glazing as claimed in claim 17, wherein the additional coating in the form of enamel or lacquer is deposited on top of the stack of layers.

19. A multiple glazing, comprising:
the glazing as claimed in claim 1.

20. The solar protection glazing as claimed in claim 1, wherein said substrate is a glass substrate.
